(19) United States
(12) Patent Application Publication
(10) Pub. No.: US 2026/0039321 A1
(43) Pub. Date: Feb. 5, 2026

(54) Digital Carrier Radio

(71) Applicant: Marvin Motsenbocker, Kamijima (JP)

(72) Inventor: Marvin Motsenbocker, Kamijima (JP)

(21) Appl. No.: 18/793,755

(22) Filed: Aug. 3, 2024

(51) Int. Cl. H04B 1/04; H03F 3/19; H04B 1/16

(52) U.S. Cl. CPC H04B 1/0475; H03F 3/19; H04B 1/16; H03F 2200/451

(57) ABSTRACT

Digital communication techniques and devices to implement them are described. By removing resonance hysteresis from the transmitter and receiver, and by accelerating electrons with direct current pulses in a non-resonant antenna, short photon time length pulses are transmitted and received. This allows single wave cycle control of the carrier used in radio transmissions.

### CROSS-REFERENCE TO RELATED APPLICATIONS

This application receives priority from U.S. Provisional application 63,530,982 filed Aug. 6, 2023 with Marvin Motsenbocker as named inventor.

### BACKGROUND OF THE INVENTION

Radio communications technology began with a spark transmitter that Marconi commercialized more than one hundred years ago. Sparks from his transmitter evinced a very large range of frequencies of radio waves associated with a high voltage electric pulse between two metal balls on electrodes and generated by a transformer. Because of the wide variety of radio waves produced by the early spark transmitters, different stations interfered with each other. The invention of the resonant circuit allowed selectivity for a preferred frequency. These resonant “tuned” circuits both at the transmission side and the receiving side allowed the use of narrow frequencies and thus multiple simultaneous transmitters in the radio spectrum. Today, resonant circuits and antennas are used throughout modern systems to help maintain signal purity, and modern wireless communications cannot exist without them.

Modern equipment such as cell phones generally contain a number of resonators, and filters, which rely on principles of resonance to select frequencies. A generally underrecognized problem with this is that all resonant components and systems require time to function. Each stage of a wireless communications device typically employs a resonant filter, which limits the time response (and overall data speed).

The entire wireless communications industry has developed resonant circuits as key components based on the wave theory of radio transmission. According to this theory a wave train is used to represent information between a transmitter and receiver. Furthermore, the Fourier transform equation taught in engineering schools explains that as the number of cycles in the wave train decreases, the bandpass (number of unwanted frequencies) increases and that it is impossible to communicate via individual photon sized signals only 2 pi radians (360 degrees) long.

Heterodyning signals through filters, with the attendant time delays is relied on to this day for radio communications. Although rarely considered, the use of wave theory, Fourier transform, and resonating filters cause delay in sending information and require bulk (non-information containing carrier) energy to create, send and receive resonating signals for information transfer. “All filters have time delay, a truth that cannot be avoided.” (page 3.23 from Experimental Methods in RF Design Revised First Edition published 2012 by the ARRL and authored by Hayward, Campbell, and Larkin). There seems to be very little attention paid to these problems, which are taken for granted. But each resonant filter, including resonating antennas themselves, creates a delay in the signal. This unavoidable truth becomes a problem for the circuit engineer when the delay changes for different frequencies that pass a filter. And, each amplifier has a delay based in part on the frequency response. See for example “Time Response of an Amplifier of N Identical Stages” in Proceedings of the I.R.E. July 1948 pp. 870-871 by Eugene F Grant.

It is axiomatic in electrical engineering that a signal must be represented by multiple cycle (ie. many multiple radians) of time duration with respect to the signal being transmitted or considered. In other words “the narrower the pulse, the wider of the spectrum . . . As the pulse becomes narrower and narrower, approaching 2 pi radians, the frequency spectrum (of that pulse) spreads out more and more” making it impossible to capture just a 2 pi radian signal (p. 15.11 of ARRL Handbook for Radio Communications).

Accordingly, multiple waves of a carrier frequency are used to ferry each bit of information in the form of 0's and 1's as well as regular analog signals, starting with Armstrong's pioneering work using AM and FM to ferry audio signals almost 100 years ago. And, a very rich set of alternative digital modes are now available for transmitting basic 0 and 1 signals using wave trains. But the energy needed for multiple wavelength cycles of energy per data in this physical layer of communication is real but basically ignored. That is, energy is used to make a resonating carrier and a signal is impressed on that carrier to carry the information. The carrier is always made and processed by resonating circuits, which truthfully cause delay, and actually consume energy. Waves and waves of energy are used to transfer each single bit. This large time and huge energy expenditure is taken for granted. It should not be.

### SUMMARY OF THE INVENTION

The problems of delay and the requirement for carrier energy to transmit information are alleviated by using single photon sized pulses instead of wave trains to represent information in radio communications. The term “radio” in this context means a device that transmits and/or receives electromagnetic energy, in a wide range of energies, including audio (eg. AM, FM, cellular telephones and the like), video (eg. Television, smart phones, wifi, satellite communications and the like). The term “photon” refers to energy associated with a single wave length energy, which may be visualized as a photon, or pulse of photons. A “pulse” of photons in an embodiment refers to a group of photons emitted at the same single time and which are coherent with each other. Generally, the photons in the pulse are traveling in the same direction and are in phase with each other. When the pulse encounters a non-resonant antenna in a embodiment the pulse generates a single corresponding wave of electron movement in the antenna.

It was discovered that placing time periods of no energy between photon pulses allowed components of a communication system, such as “non-resonant” antennas and single pulse use crystals to relax and dissipate unwanted energy between adjacent photon pulses. This is because even a “non-resonant” antenna has a little bit of residual resonance that ideally should be allowed to decay before accepting a new photon pulse.

In an embodiment, individual 360 degree cycles are successively selected or controlled to impart information to the resulting composite energy output as one or more waves or pulses of photons, which comprise the carrier signal. In one embodiment, two separate signals 180 degrees out of phase are generated as individual bits in a successive chain of cycles by flipping the phase to distinguish between logic ones and zeroes. A wide variety of procedures can be employed as will be appreciated by a skilled artisan, including fast H bridge circuits, push-pull circuits with alternative driving, and the like. In embodiments other phase changes and even combinations of different frequencies of transmissions may be combined. The examples focus on 180-degree phase flipping for brevity.

The term “circuits” used herein includes software. A skilled artisan will appreciate that many circuit activities can be performed either in software, via hardware, or combinations of both. For brevity and to show the basic examples, basic circuits are presented in the figures. However, such circuits generally can be replaced by microprocessor driven functions. This is particularly true as microprocessor speeds increase and can sample and control signals, particularly at the lower frequencies (eg. less than gigahertz, particularly less than 250 MHZ) although eventually even the very highest frequency signals can be individually sampled and generated on a cycle by cycle basis in real time, as the hardware advances.

One embodiment is a method for communicating information via a non-resonant radio signal comprising absorbing electromagnetic energy with an antenna to create a series of 2 pi radian duration pulses in a conductor with respect to their frequency, detecting zero crossings of the pulses;

wherein the series of pulses are non resonant and determining at least one of: time polarization of pulses; time between zero crossings of the pulses; and frequency (photon energy or wavelength) of individual pulses to recover binary information as logical ones and zeros.

Another embodiment is a photon pulse radio frequency communication system, comprising a transmitter that emits individual cycle pulses of electromagnetic waves separated by non-energy blanking times and a receiver that detects the individual pulses of electromagnetic waves, wherein each pulse is a single radio wave.

Other embodiments readily will be apprehended by a reading of this specification.

### BRIEF DESCRIPTION OF DRAWINGS

FIG. 1 shows prior art modulation of wave trains.

FIG. 2 shows an embodiment.

FIG. 3 shows a transmitter embodiment.

FIG. 4 shows a transmitter embodiment.

FIG. 5 shows a transmitter embodiment.

FIG. 6 shows a receiver embodiment.

FIG. 7 shows a transmitter embodiment.

FIG. 8 shows data for a transmitter embodiment.

FIG. 9 shows a block diagram for a transmitter embodiment.

FIG. 10 shows a transmission test setup.

FIG. 11 shows data from a receiver embodiment.

FIG. 12 shows data from a receiver embodiment.

FIG. 13 shows data from a receiver embodiment.

FIG. 14 shows a schematic for a transmitter embodiment.

FIG. 15 shows a schematic for a transmitter embodiment.

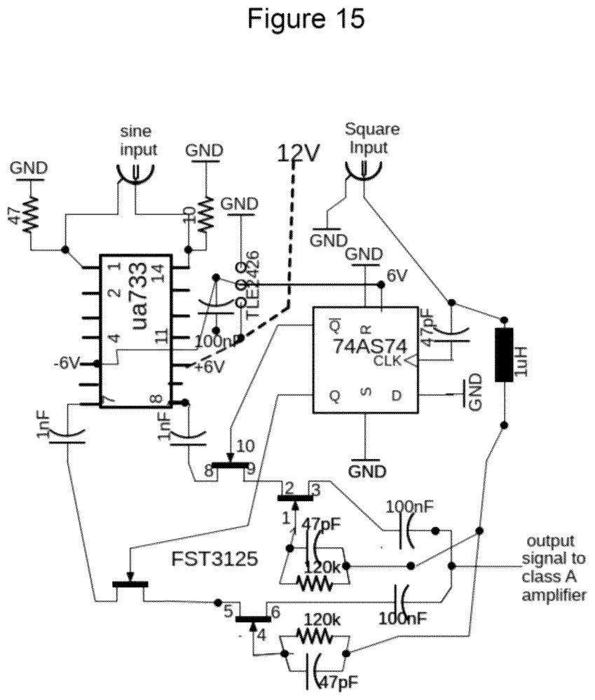

FIG. 16 shows a schematic for a transmitter embodiment.

FIG. 17 shows a schematic for a transmitter embodiment.

### DETAILED DESCRIPTION OF THE INVENTION

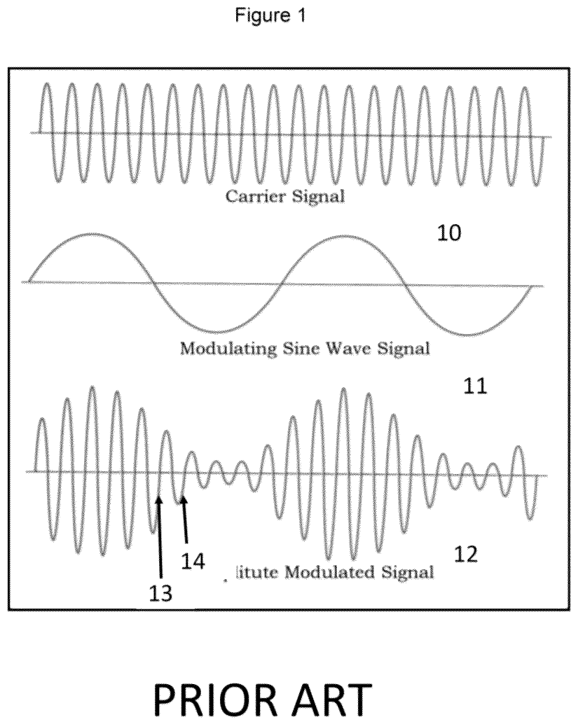

FIG. 1 shows prior art signal configurations used in typical communication. In a prior art resonance system shown here, typically a carrier signal is created and used to ferry information that is modulated into it. This example shows carrier signal 10, modulating sine wave signal 11 and composite amplitude modulated signal 12 created by heterodyning signals 10 with 11. This is an example of simple amplitude modulation but a very wide variety of modulations are now used for modern radio frequency communications. Typically many (10-100 or more) 2 pi radians of wavelength are used to carry a single bit of information. In contrast, arrows 13 and 14 show the beginning and end of a single photon wavelength within this much larger series of photon transmissions.

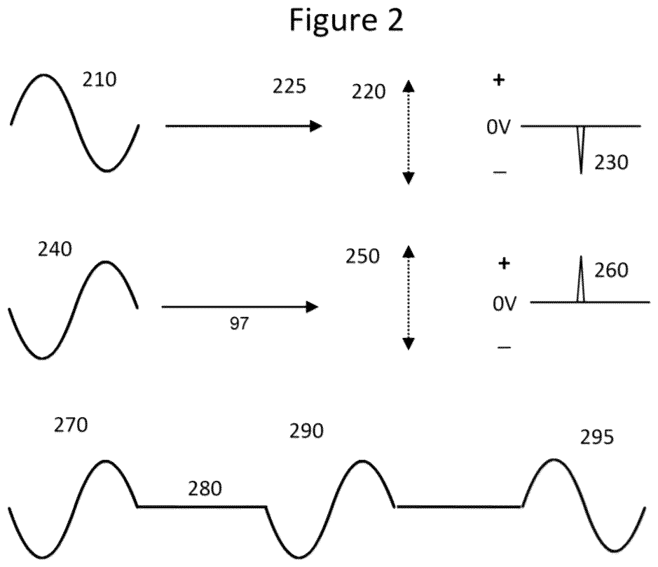

FIG. 2 shows an embodiment of the invention wherein individual photon pulses are used for communication. Individual photons are depicted in the figure and discussed here, although it will be understood that in practice, large pulses of synchronized photons are normally used for broadcasting information to get over noise. In an embodiment however, one photon at a time may be used in a manner analogous to that being done with entangled photon communications.

The photon (pulse) 210 shown in this figure has an electric field that changes in the 220 axis vertical vector. This travels in the direction of arrow 225. The photon later may encounter a receiving wire or antenna metal and induce an electron movement pulse 230 in that metal, which is detected in a receiver. A photon pulse 240 of the opposite orientation (or spin) with the electric field vector 180 degrees out of phase in the same vertical vector direction 250 will make a very different pulse 260 in that receiver (not shown).

It was discovered that separating subsequent pulses 270 and 290 via a pause-time 280 was helpful to receive the pulses with minimum distortion. Preferably spacer delay between pulses 280 is at least half of the time size of the preceding pulse. In the example shown, spacer 280 should be at least pi radians (one-half the size of photon pulse 270), which immediately precedes spacer 280 in time. In preferred embodiments photons 270 and 290 have the same wavelength and spacer 280 is also the same 2pi radians time duration as those pulses. In an embodiment an inversed second pulse 295 is combined with transmission to get two types of signals in a common signal train. This is preferred because a roughly equal number of both types can be used in a channel occupied by a legacy wave-train signal of only one type without severely affecting the receiver as noise. The two types of pulses neutralize each other in the resonant filters of other receivers.

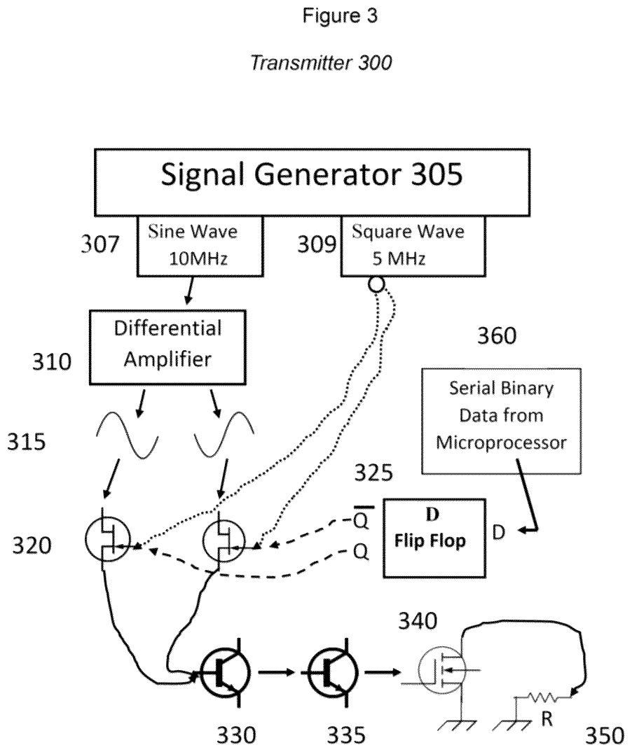

FIG. 3 shows a transmitter 300 that follows the simpler method of using equal sized plus and minus bits and spacers between the bits. This uses a signal generator 305 that outputs sine waves 307 and square waves 309 synchronously. A differential amplifier 310 generates two sine waves 315 that are 180 degrees out of phase with each other. Enhancement mode JFETs 320 connect these opposite signals to an amplifier shown here as NPN transistor gate of 330. At the same time and in parallel, the 5 MHz square wave 309 triggers the two JFET valves to turn on and off every other 2pi radian time. This creates a space between photon pulses.

Each allowed pulse is either a 0 bit or 1 bit depending on the output from flip flop 325. The output of 325 as shown here as active low. In other words, when Q or not Q is low, a low impedance to ground is provided to the attached JFET gate, which effectively turns off that JFET. Thus, either a logic 1 or 0 is always provided from flip flop 325 to the JFET values 320. A microprocessor or computer 360 feeds the desired data (0 or 1) in a serial manner to the flip flop (D flip flop is preferred). The correct signal is then amplified by an amplifier, which in this example is made up of transistors 330, 335 and 340. The amplifier output stage feeds a non-resonant antenna 350. It is important to avoid handling the separate photon pulses with a tuning circuit. For this reason class A wide band amplifiers without band pass, low pass or high pass filter are preferred.

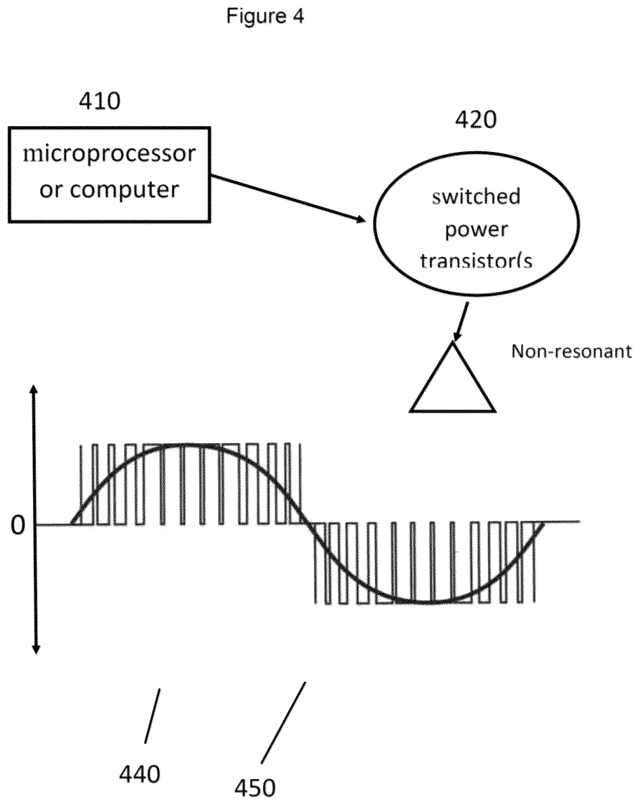

The transmitter example in FIG. 3 shows what can be done with analog circuits. In a preferred embodiment, individual photon pulses are synthesized by a microprocessor or computer as shown in FIG. 4. Here, computer 410 creates a pulse width modulation signal, with a pattern as seen in in the vertical lines 440 and zero crossing 450 of this figure. The PWM signal switches a transistor 420 which, after switching may allow a small amount of capacitance to smooth the signal (not shown) and then feeds non-resonant antenna 430. In this way PWM signal 440 can be synthesized by a computer based on desired frequency and (if used) blanking pause between photons and converted into discrete photons upon application to non-resonant antenna 430.

In another embodiment individual photon pulses are separated by pauses by selectively shorting out an antenna that has a continuous sine wave feeding it.

### Definitions

### Non-Resonating Wavelet

An NRW, or non-resonating wavelet is here defined as a wave-like smooth continuous wave with an amplitude that begins at an initial value, increases or decreases, and then returns to that initial value one or more times. In a preferred embodiment an NRW is a smooth continuous wave of the sine trigonometric function that returns to the initial value once, and resembles a half sine wave, or returns to the initial value twice, and resembles a complete sine wave. In an embodiment the NRW has a repeating amplitude that returns to the same initial value multiple times and may even resemble a standard wavelet, but is not resonating.

NRWs described in this disclosure may represent pulses of electrical energy applied to a wire and may represent electromagnetic energy as photons created from pulses of electrical energy. In many cases the NRW represents an acceleration of an electron and can be characterized by having a positive acceleration (increase in electromotive force) or negative acceleration (decrease in electromotive force) that occurs in a smooth sinewave like manner.

Examples in this disclosure teach the meaning of this term via usage and are not limited by this written definition.

### Photon

A photon is the smallest packet of electromagnetic energy and in a preferred embodiment is an NRW of electromagnetic energy that is a wave-like smooth continuous wave with an amplitude that begins at a zero, and either increases or decreases, and then returns to zero once, or both increases and decreases (in either order), and returns to zero two times.

### Purified Photons

The term “purified photons” refers to multiple photons made having the same frequency and at primarily the same location i.e. from the same antenna. A photon may exist as a half wave as a smooth continuous wave with an amplitude that begins at zero, and either increases or decreases, and then returns to zero once. This type of photon has half the wavelength of a photon that exists as a full wave wavelength and has a spin of +1 or −1. A purified form of these photons may for example consist of multiple photons made by a wire having metallic bonding electrons such that acceleration of multiple bonding electrons results in many photons of the same wavelength and direction emitted perpendicular from the same location. Preferably at least 99 percent of the half wave photons have frequencies that are within 0.1 percent of a mean average.

### Non-Coherent Photons

These are photons that do not participate adjacently and continuously with others of the same wavelength to join a common wave train of successive crests and troughs. If two photons are contiguous in time and form part of a sinusoidal wave train, then they are coherent with respect to each other.

### Non Resonant Antenna

The term “non resonant antenna” in an embodiment refers to an absorber of energy that does not resonate, or ring and which preserves the waveform (as a single wavelength) of a photon pulse.

### Non Resonant Asynchronous Pulses

The term “non-resonant” in an embodiment means that individual sine pulses are not arranged synchronously. In typical prior art wireless communications electromagnetic energy is emitted as a continuous series of waves that are synchronous with each other. In contrast, asynchronous wireless communications as used herein can include individual (2 pi-radians long individual sine wave) pulses or even pi radian long half sine wave pulses that may be separated by blank spaces (absence of pulse energy) and/or separated by one or more pulses.

### Pi Radian-Long Half Sine Waves

Pi radian-long half sine waves occupy only half of a wavelength. For example, a 10 MHz sine wave has a 30 meter wavelength where each wave occupies 100 ns. A + spin photon of 10 MHz has a 100 ns 30M wavelength that is opposite polarity of a − spin photon of 10 MHz, with a 100 ns 30M wavelength. These sine waves photons are supposed to be the smallest unit of electromagnetic energy. However, evidence was obtained that half size sines can be transmitted and received. Because this is a major departure from dogma, the experimental evidence in support of the smaller photon size is presented in the second portion of this specification.

### Photons and Signals

For purposes of this disclosure, the term photon and signal are not abstract representations of information but are real substances. It is assumed that a photon has the properties of two spin states, forward and reverse. A “signal” in this same context represents either a pattern of photons and/or the resultant physical pattern of physical changes that such photons cause in a circuit. For example, photon energy can be absorbed by electrons in a wire antenna and this absorbed energy can be detected as a spike in voltage or current in time at a point on the antenna (such as a feed point to an amplifier) or by a change along a distance of the wire antenna. Later, this same pulse can be modified, amplified, or otherwise analyzed as a real thing by circuits and by computer processing of detected signals.

### Digital Signals

In an embodiment signals and photons may represent 0 and 1 bits by their presence or absence. Signals and photons may be separately polarized. See FIG. 2, which shows two signals of equal time period but that are inverted with respect to each other. For example, signal 210 has a first increase in electric vector followed by negative vector, and which can cause a positive electron flow (ie. movement of electrons away from the source of the signal when intercepted by an antenna) is termed positive bit or “1” bit. Without wishing to be bound by any one theory for how embodiments work, it is believed that forward spinning +1 photons and reverse spinning −1 photons are being separately generated or transmitted and separately detected. The term “polarization” may be used interchangeably as spin in discussion of embodiments.

The pictorial suggestions are made by supposition to help the reader understand the basic concepts but are considered wrong or incorrect from various vantages. These are presented without intention of being accurate or a limitation to the claims but are helpful as an introduction to new kinds of digital signals.

### Embodiment: No Modulation/Demodulation Via Mixer(s)

In preferred embodiments information is embedded into a wave train via individual control of individual cycles. However, in an embodiment the information is synthesized into a wave train as a small group (eg. 2, 3, 4, 8, 10, 64, 100, 128 etc.) of cycles for each bit. In a preferred embodiment this is done in the absence of mixing/modulation with another frequency in a mixing step. Afterwards, the successive waves may be amplified (preferably with a linear amplifier) and sent out over an antenna that preferably is tuned with low SWR mismatch (preferably less than 3, more preferably less than 2, more preferably less than 1.5 and most preferably less than 1.2) so that successive waves can radiate out with distinguishable phase relationships with respect to each other. In an embodiment, such phase-shift information containing waves are used for another (dual use) purpose such as for CW transmission or another transmission. In an embodiment that second use transmission can employ a mixing step for modulation.

### Generating the Discontinuous Phase Signal: The Transmitter

A wide variety of techniques can be used to make discontinuous waves as contemplated herein. Hardware (circuits) and software can be used together and, in many cases can substitute for each other. For example, a signal can be made purely by hardware, but if a microprocessor speed is high enough with respect to the signal, and timing of I/O is not an obstacle, most signal shaping can be done by software run on a machine that for example can output waveforms in digital form. However, hardware devices are convenient and robust for generating phase shifts, and can be easily controlled by a computer that can instruct a bit pattern to encode via phase shifting. In an embodiment, a frequency generator creates a sine wave or square wave that is modified to add the bit information. In another embodiment, phase information is added at the output to an antenna stage, whereby rapid antenna switching is used to create phase shifts that corresponds to bit information. In yet another embodiment the information encoded is not limited to 0.1 bits but may be 3 bits or more for example by changing the time spacing between pulses or adding another frequency for simultaneous transmission.

In an embodiment a dipole antenna is switched in a bipolar manner to obtain bipolar phase changes. Preferably the switching is done at or as close to the zero signal level as possible to prevent generation of unwanted harmonics. For example, when switching an antenna, it is helpful to position the switcher electrically at a node where standing waves present a minimum voltage and current.

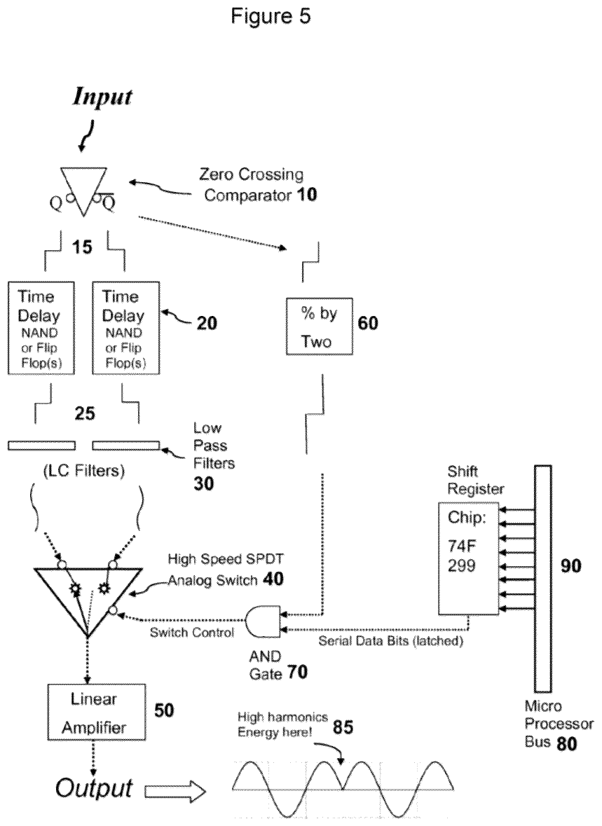

An example of a transmitter scheme is given in FIG. 5. Here an input may be a square wave or sine wave. A comparator 10 acts to create two outputs (Q and Q′, which are opposite phase to each other. By generating square waves 15, well matched opposite phased signals are easily generated. Optionally, these signals are delayed (example NAND gate buffers, flip flops 20) to allow the switching of an analog switch to better match the zero crossing time. After optional time delay, the out of phase square waves 15 are converted to out of phase sine waves 25 via low pass filters 30. The two alternate sine waves then are presented to analog switch 40, which will select one or the other phase for a single cycle to send out for further amplification by linear amplifier 50.

Meanwhile, one signal from comparator 10 (top right side of FIG. 5) is divided by two via circuit component 60 to create a logic 1 (or zero) corresponding with a complete cycle. This may be for example a fast edge triggered d-type flip flop. The output of component 60 is combined with a bit signal output by AND gate 70, to select one complete cycle of either of the two out of phase signals. Microprocessor bus 80 (or other input) from a microprocessor (not shown) dumps desired bit sequence information into shift register 90, which outputs one bit at a time into AND gate 70. In an embodiment a differentiated pulse output from comparator 10 (not shown) is used to trigger the shift register to shift its data bit, which are latched and readable by AND gate 70 during a single complete cycle. Filters preferably are used to remove the high frequency components 85.

Analog switch 40 here is a single throw double throw switch that selects one of two phase changed signals depending on the serial data bit (1 or 0) received by AND gate 70 from microprocessor bus 80. The output of analog switch 40 is amplified by linear amplifier 50, which preserves the phase differences of successive cycles.

In an embodiment, a fast microprocessor outputs a desired high frequency signal that is phase shifted corresponding to data, as directed by software using a rapid D to A converter to create 360 degree (complete) individual sine waves of shifted phase. In a desirable embodiment no mixer is used to create the output signal. In a desirable embodiment sidebands are removed such as by using an I/Q chip that outputs out of phase sideband signals that are used to remove sidebands.

### Detecting the Discontinuous Phase Information: The Receiver

A large variety of detection schemes may be employed to obtain bit information from individual cycles, preferably without a mixing (demodulation) step. For example, a zero crossing detector can be used to detect timing of individual cycles. At 90 degrees from the zero crossing points (based on a timing signal generated by 180 degree delay/lag from individual zero crossing signals) a signal measurement can be made. A comparator preferably is used here to detect maximum positive (or negative) voltage at that 90 degree shifted location in the cycle. A phase change (or reversal) leads to different timings and also to different polarities. Sensed information preferably is sent to a microprocessor for information extraction.

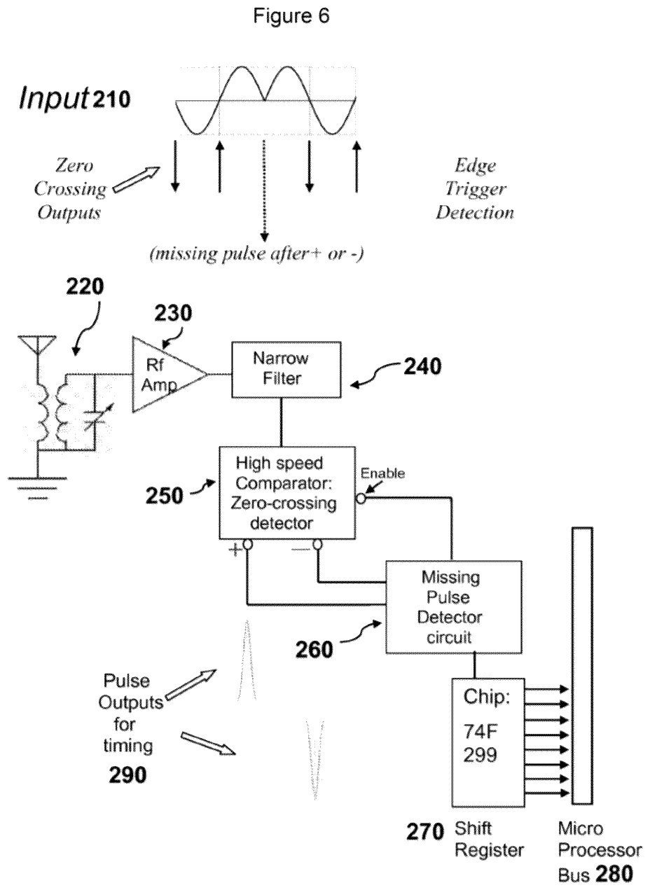

In a preferred embodiment shown in FIG. 6, phase information from a signal 210 is extracted by generating negative pulses (down arrows from 210 shown in FIG. 6 and positive pulses (up arrows) for each zero crossing. A practical receiver can use such detection as exemplified in FIG. 6. Here an antenna tuned circuit 220 feeds Rf amp 230. An amplified signal from Rf amp 230 feeds narrow passband filter 240. Preferably filter 240 has a passband (−10 db points on either side) of less than 200 hertz, more preferably less than 100 hertz yet more preferably less than 50 hertz and even yet more preferably less than 10 hertz. The output of narrow filter 240 optionally is amplified again (not shown) and then is resolved by comparator 250.

In this embodiment comparator 250 outputs negative and positive pulses 290 for descending and ascending zero crossing points respectively. Missing pulse detector 260 determines if a missing pulse follows a positive (zero crossing) pulse or a negative (zero crossing) pulse, and sends that information to register 270. Register 270 loads information in parallel format onto microprocessor bus 280.

Preferably these circuits use emitter coupled logic. Circuit 260 for example could be made from using a pulsed output from comparator 250 to time (enable) a sensing of the signal at 90 degrees after the zero crossing. If no signal (either positive or negative) is present 90 degrees after the zero crossing, then a bipolar phase inversion has taken place. An analog phase shift amplifier or RC characteristic could be used to set a 90 degrees delay strobe timer pulse. Then the strobe signal can activate an AND gate or analog switch to check the status of the signal at the strobed time point.

### Photon Pulsing

In a more desirable embodiment specific pulses of photons are separately created in a manner that minimizes harmonics and bandwidth. In a particular embodiment, the problem of harmonic energy generation (undesirable mixing and harmonic frequencies 85 indicated in FIG. 5, bottom) are removed by: a. generating specific cycles separated in time from each other, and b. shunting, shorting or otherwise blanking the signal chain at one or more locations during the time (preferably between successive cycles) when no cycle is made. In a simplest mode, alternate cycles are generated with evenly spaced blank times between them, preferably corresponding to integral cycles times. Preferably a low impedance is presented to the signal chain at least at the first analog signal output step having the blanking time period, during that time period.

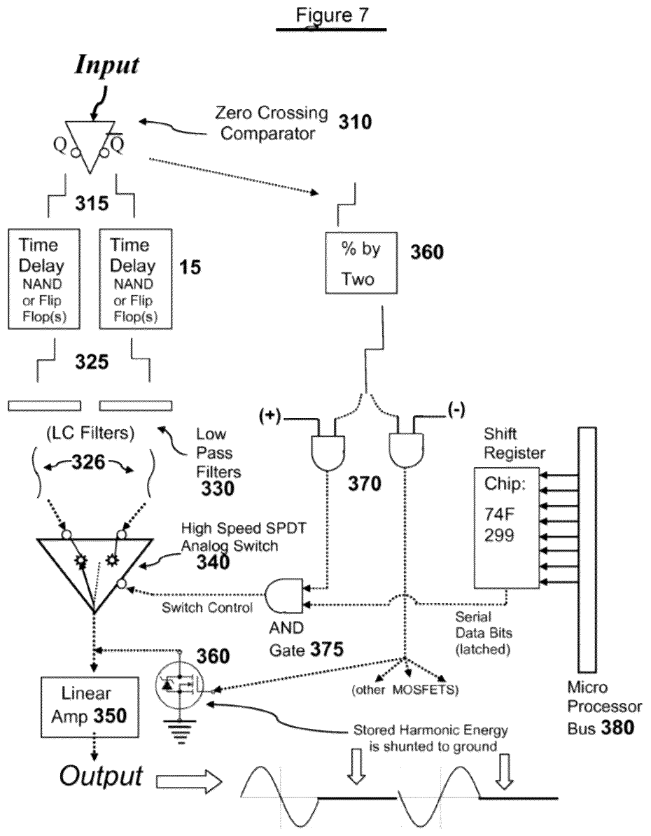

In FIG. 7 an input signal such as a regular repeating square wave or sine of known frequency (or shifting frequencies) inputs to zero crossing comparator 310. In an embodiment this comparator is not needed and a square wave is used instead. The square wave is converted to opposite phased signals. In an embodiment shown in FIG. 7 the signals are exposed to a time delay via circuit 15, although in other embodiments the timing issues may be taken care of without circuit 15.

After optional circuit 15, the two signals 325 are filtered by low pass filters 330 to generate oppositely phased sine waves 326. The sine waves are separately selected by high speed analog switch 340, which is controlled by AND gate 375. In this particular embodiment AND gates 370, controlled by divide by two counter 360 provides alternative photon pulse and blanking times. Signals from a microprocessor (not shown) may be provided by bus 380 or other conduit to cycle in data that in this embodiment shows up as two different phased and independent signals separated by blanks.

In order to ensure better blanking (decrease harmonics and other signals during the blank time), MOSFET shunt 360 is activated. MOSFET shunt 360 is controlled by AND gates 370 in this example so that a low impedance from MOSFET 360 is impressed during the blank time when switch 340 does not allow a signal 326 to pass. MOSFET 360 also helps limit ringing between successive signals by discharging resonance energy between each generated cycle.

The generation of isolated cycles as shown in FIG. 5 can be achieved by a variety of methods. A key point in many embodiments is to provide a low impedance load to shunt resonance energy during a blank time. FIG. 5 exemplifies the use of alternating blank times and the use of bipolar cycles. Other combinations are possible, such as multiple cycles (eg. 2-3, 4-10, 10-50) separated by one or more blank times. Also, mono polar cycles can be used, and multipolar (eg. 90 deg, 180 deg, 270 deg, 0 deg, or other combinations) phases may be used to provide more information for higher data density.

The preferred low impedance blank preferably is used at two or more locations in a signal chain. For example, a blank-time-only low impedance switch may be imposed before, within, or after each stage of amplification. In an embodiment this is also imposed at the antenna or transmission line. In an embodiment the blanking is carried out anywhere where a high Q tuned circuit exists, in order to limit ringing of such circuit. As skilled artisan will appreciate how to control signal purity based on analysis of stray inductances and stray capacitances. Capacitance of devices such as MOSFETs or IGBTs used should be minimized by selecting a small device that is still adequate to handle the expected shunt load. In an embodiment however, the device capacitance is used to form a filter. In an embodiment one or more filter circuits are used having low Q (less than 2, less than 5 or less than 10) to minimize ringing.

In an embodiment two or more signals are generated and used simultaneously to drive two or more antennas in a phased relationship. In an embodiment a low impedance shunt is added to an antenna or transmission line to decrease resonance, and in an embodiment that low impedance shunt is switched in added during a desired blank time. In an embodiment each cycle is separated by two cycle-blank times. In an embodiment each cycle is separated by three, five or up to 10 cycle blank times, in order to minimize resonance energy from one cycle spilling outside of that cycle time. In an embodiment every resonance circuit at the amplifier and antenna stages is shunted during one or more blank times to minimize ringing.

### Use as a Physical Layer for Communications

A wide variety of signaling systems can employ physical transmission and reception and signals described herein. In one embodiment, bits are associated with spin states. Opposite spin states can correspond with 0s and 1s for example. Partial phases such as quadrature can be used for bit systems. In an embodiment, phase changes can correspond to bits. In yet another embodiment, timing, such as how many blank periods within a period of time or between signals, are associated with bit information. Communication systems used for networking provide a huge variety of error correction methods, formatting methods and control methods and are intended for use with embodiments. Particularly desirable are TCP/IP and other data management protocols for use in network communications. In this regard, the methods and devices described in “Computer Networks” by David Wetherall (ISBN 0132126958) are particularly incorporated by reference in their entireties. The embodiments described are useful for shortwave (3 MHz to 50 MHz) systems, wherein individual waves and wave pulses bend and bounce, and can particularly benefit from phase error correction methods to accommodate phase changes during communication.

### 180 Degree Wavelet Examples

In order to make pure pulses of isolated groups of photons, transmitting circuits were developed that periodically accelerate electrons in an antenna for selected sections of a wave form. This was difficult to do with existing circuits and all non-resonant circuits were developed and without frequency filters. The first section of results describes the resultant new transmitter operation. In the second section of results, the transmitter is used in combination with a non-resonant receiver to produce and record the generation of one-half wave and full wave length photon signals separated by blank spaces of adjustable duration, and at two different frequencies.

### Generation of Individual Wavelets at 10 MHz Frequency

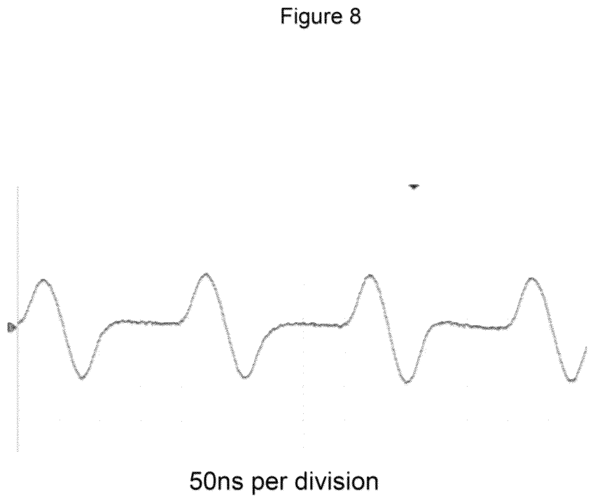

Isolated 10 MHz wavelets between 180 and 360 degrees (50 to 100 ns long) were generated at set intervals and used to find appropriate circuits for the transmitter. FIG. 8 is an example of such waveform applied to the output stage of the final amplifier after 2 stages of amplification. The electron pulse signal of FIG. 8 was used to excite the last, high voltage stage in the transmitter to accelerate antenna electrons. All accelerations were direct current to avoid resonance and wave making. Even small deviations from this caused devolution of a single pulse into a repeating wave, usually of the same frequency as the original pulse. Thus, electrons were accelerated in a single direction using direct current excitation of an antenna. Frequency filtering was strictly avoided.

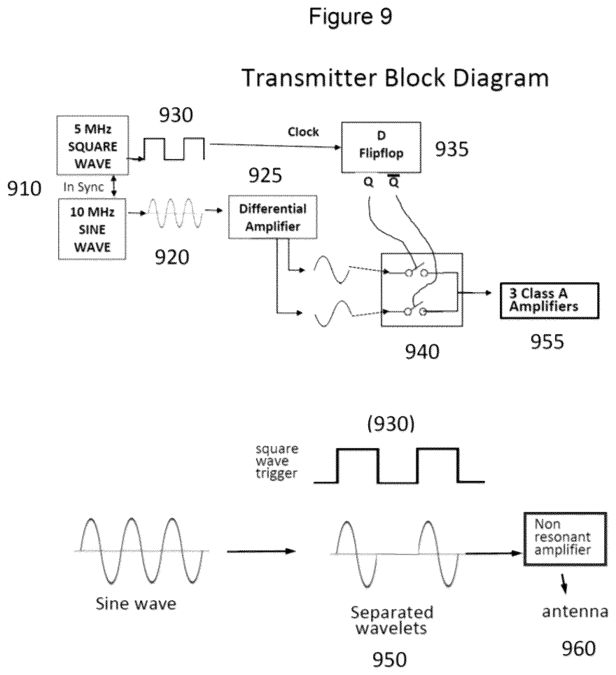

FIG. 9 is a transmitter block diagram of the circuit that generated the wavelets by allowing selection of portions of a sine wave to be amplified in the transmitter. At the left side is two channel signal generator 910 that output 10 MHz sine wave 920 to differential amplifier 925 and output 5 MHz synchronized square wave 930 as a clock signal to D flip flop 935. The square wave 930 was used to block every other sine wavelet in 920 via fast JFET switch 940. The square wave duty cycle was typically adjusted to 50% but was increased in some experiments to 75% or 88%. The resulting intermittent signal of separated wavelets 950 was amplified to typically 60-70 volts direct current by class A amplifiers 955 and connected to antenna 960, for accelerating metallic bonding electrons.

Each wavelet was isolated from the others to avoid resonance and the formation of standing waves. Most traditional radio frequency amplifier circuits caused collapse of the signal into a continuous wave train, while acceptable “clean” circuits preserved the separate wavelets.

Detecting Wavelet Signals from the Transmitter

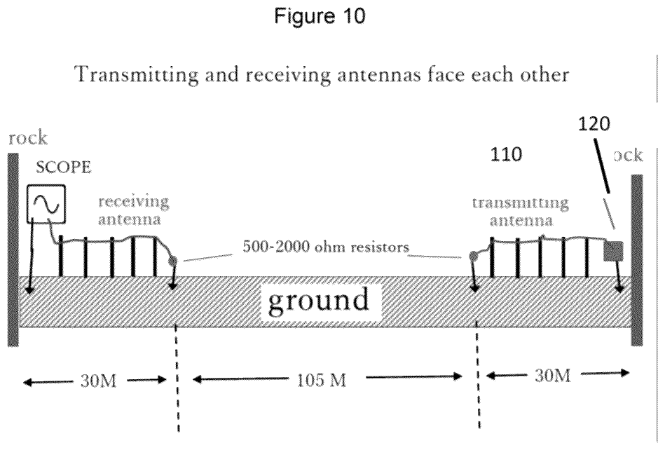

Two beverage antennas 30 meters long and 2 meters high above the ground were constructed facing each other and pointing along the same radial line as shown in FIG. 10.

The electrons in transmitter antenna 110 were excited by direct current separately applied in one or the other direction at a time using repeated 180 degrees (half wave) 50 ns pulses separated by 150 ns between each, from a 10 MHz sine wave source in transmitter 120. The transmitter 120 was adjusted to accelerate antenna circuit electrons only during the first 180 degrees half of every four 10 MHz sine waves by setting the sine wave to 10 MHz and setting the square wave to 5 MHz with a 75% blanking duty cycle. This created 50 ns pulse accelerations in the wire followed by 150 ns of blanking (no force) applied to the antenna.

Photon emission results were obtained by accelerating the antenna electrons first in one direction from the transmitter direct current output. Then the antenna connections were reversed and the antenna electrons were accelerated in the opposite direction.

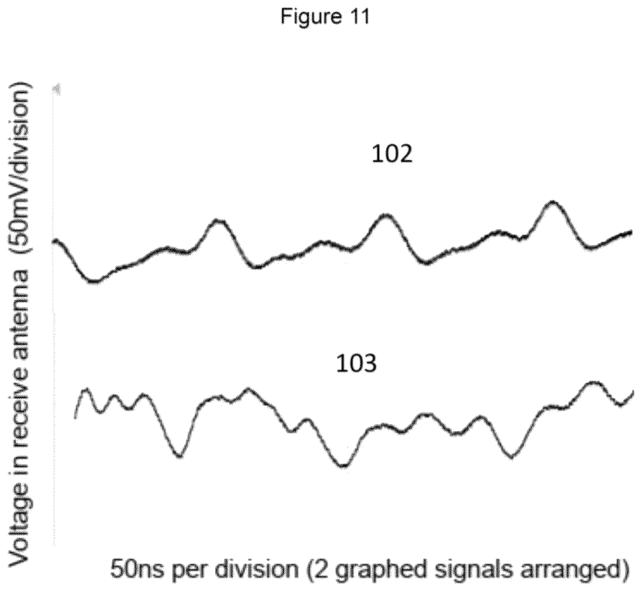

The top plot 102 of FIG. 11 shows that positive going pulses of excitation to the metallic bond electrons in the wire caused similar shaped positive pulses in the receiver antenna as indicated by the scope output reproduced here.

After the transmitter antenna connections were reversed the receiver sensed photons that made opposite pulses in the receiver wire, as shown by the scope recording at the bottom of FIG. 11. The lower plot 103 of FIG. 11 shows the response of the receiver to this reversed electron energy acceleration. The electron flow pulses in the receiver antenna have been reversed (changed polarity). The upper and lower traces were obtained at different times with different trigger levels and therefore their peaks do not overlap. Importantly, the received signals are pulses, which can be detected as communication bits, not complete sine waves. Each 50 ns pulse is followed by a small amount of resonance during a 150 ns pause as 3 smaller voltage peaks possibly due to non-linearities in the last transmitter stage.

### Vary Electron Acceleration Periodicity and Wavelength

Acceleration of electrons in the antenna was varied by adding longer spacing between accelerations.

The square wave generator was adjusted to 2.5 MHz and 82% duty cycle to blank out a 10 MHz sine wave train. This forced the transmitter to apply a direct current acceleration voltage measured at 0-70 maximum volts to the antenna over a time period of 50 ns every 400 ns.

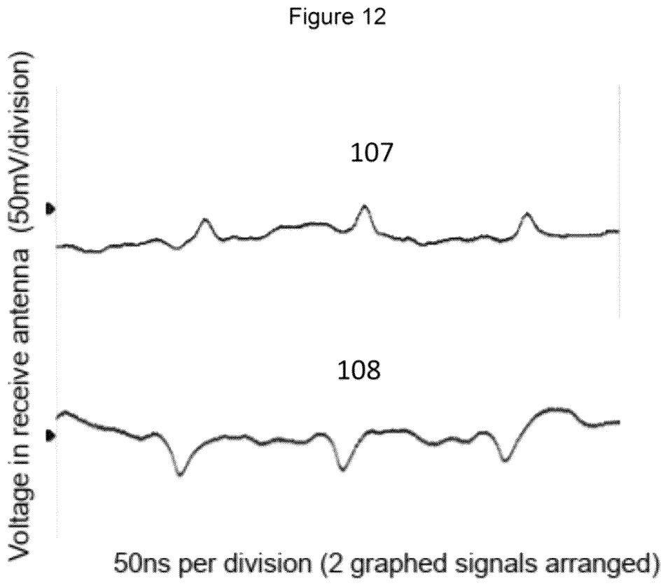

These accelerations produced 50 ns wide single direction pulses 107 in the receiver antenna at 400 ns apart, as shown by the scope recording in the top of FIG. 12.

The electron output from the transmitter MOSFET was directly connected to the antenna and the plus side of the 300V power supply was connected to earth ground. The electron pulses in the antenna thus were one directional from the transmitter end to the distal end of the antenna pointing to the receiver.

Next, the transmitter output connection to the antenna was reversed. That is, the electron flow from the MOSFET drain was connected to earth ground and the plus side of the 300V power supply was connected to the transmitter end of the antenna. The distal end of the antenna away from the transmitter was connected to ground. Thus, electric force traveled through ground and traveled back to the transmitter via the antenna. This caused opposite polarity pulses 108 in the receiver antenna as shown in the bottom plot of FIG. 12.

### Single 16 MHz Accelerations Compared to Sine Wave

Shorter pulses of higher frequency half sine accelerations were made in an example. The first half sine of every four sine waves was accelerated at 16 MHz. The transmitter was adjusted to accelerate antenna circuit electrons only during the first 180 degrees half of every four 16 MHz sine waves by adjusting the sine wave output to 16 MHz and adjusting the blanking square wave pulse to 4 MHz with 88% blanking duty cycle. This created 32 ns half sine shaped pulses every 250 nanoseconds.

For a control, the square wave blanking signal was turned off and the 16 MHz sine wave (in direct current) energy was applied to the antenna.

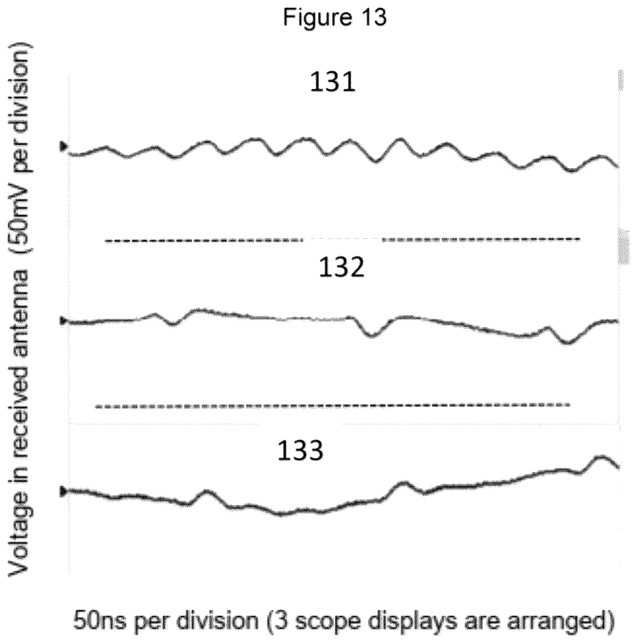

FIG. 13 shows the receiver antenna scope recordings for these 3 accelerations. The top scope display 131 is the control 16 MHz sine wave with no blanking. The middle scope display 132 from the receiver antenna wire shows approximately 32 ns unidirectional peaks of electron movement every 250 ns in the receiver wire. The bottom scope tracing 133 shows the same peaks and 250 ns periodicities in the receiver wire after reversal of the antenna connections of the transmitter.

The x-axis time and y-axis voltage ranges are roughly the same for the three signals. The forward and reverse transmitted 32 ns pulses (lower two traces) are each similar in size and shape to one half cycle segments from the received sine wave signal (top trace).

These complementary results show that two kinds of photons can be used to communicate bit information from an energy transmitter such as an electron in the transmission wire, to an energy receiver, such as an electron in the receiver wire in an embodiment. A one direction acceleration of energy in the virtual one-dimension space of a wire causes emission of a photon with assumed forward spin. An opposite direction acceleration of energy in the virtual one-dimension space of the wire causes emission of a photon with assumed reverse spin. Reversing the polarity of the transmitter connection to the antenna caused reversal of the acceleration. However, in an embodiment the reversed acceleration occurs by selection of the second 180 degree half of the sine wave signal instead of the first 180 degree half.

The relationships between the direction of acceleration electric force applied to the transmitting wire and the direction of induced electric field in the receiver wire were not affected by length of time between accelerations or by frequency. The data show that changes in the electric field sensed by the receiver in each case corresponded in duration and in periodicity with the accelerations in the transmitter wire, despite differences in intervals and change in frequency from 10 MHz to 16 MHz.

Metallic valence electrons in the transmitting wire were accelerated for half a sine wave (31.25 ns) via a quick 37V decrease in voltage over this time. The middle panel of FIG. 13 shows the consequence of that 32 ns acceleration on the receiver wire. The received pulse in the wire was 32 ns long, separated by the same 250 ns spacings and showed up as a negative dip. When the electric force changed direction via reversing connections to the transmitting antenna, an inverse polarity of the derivative occurred. The receiver recorded opposite going pulses of the same size and spacings as shown in the lower panel of FIG. 13. These dips are detected as logical bits in an embodiment.

### Examples of 360 Degree Photon Bit Communication

### Capacitive Coupling of AC and DC to an Antenna

This circuit was constructed on a small circuit board that was attached directly to an antenna without a transmission line. The antenna was a 25 meter long T2FD non resonant antenna from COMET, having a measured 1200 ohm resistive impedance. This circuit and the antenna were not earth grounded. The circuit board ground plane and the capacitor coupled drain output from the MOSFET were directly connected across the antenna leads without a balun (impedance matcher).

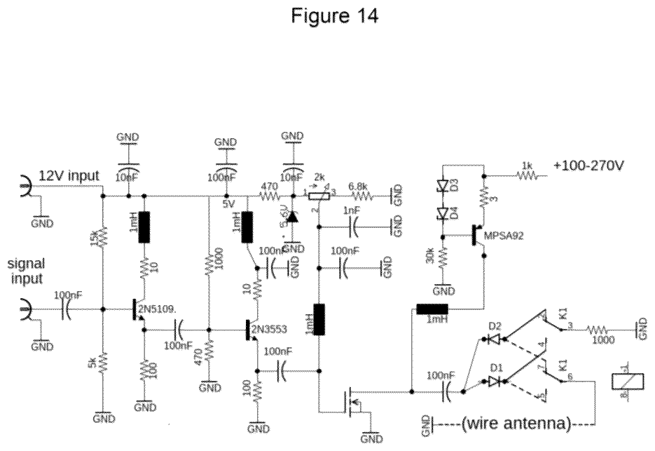

A sine wave of 0.1 volt RMS 10.15 MHz was applied to the bipolar transistor amplifiers, which output a high current signal of about 1.3 peak to peak voltage. This current amplified signal was applied to the gate of an IRF710 MOSFET that was biased for class A operation. The transmitter and T2FD antenna were located 5 meters above ground level. Circuit details of connections with alternate diodes and electron energy flow paths are in FIG. 14. This circuit amplified a 10.15 MHz sine wave supplied to it at the connection shown but separated the sine wave output to the antenna into electron flow directions according to the switch that alternately selected either diode or both diodes in the path to the antenna. In an embodiment a fast switch is used that switches between photon pulses at zero crossing points.

### Generation of + Spin, Vs − Spin Photons

The signal output of the IRF710 drain was connected to two 1N4148 signal diodes connected in opposite directions for rectification of the radio frequency (“RF”) signal before connection to the antenna. In a first example the outputs of both diodes were switched to the antenna to allow both forward and reverse electric force on the wire according to the sine wave input. In a second example the RF signal output from only one signal diode D1 as shown in the top panel of FIG. 9 was connected to the antenna. The other output from the second diode was shorted to ground via a 1000 ohm resistor. Preferably the passive diodes used here are replaced with an active switch such as a JFET transistor to switch at zero crossing.

In a third example the RF signal output from the other signal diode D2 was connected to the antenna. The other output from diode D1 was shorted to ground via a 1000 ohm resistor. In an embodiment these are switched according to a logic stream presented from a microprocessor or stored data file.

### Example: Construction of a Transmitter for Individual Wavelets at 10 MHz

The wavelet generation circuit outlined in FIG. 9 was built with a wavelet generation portion, and a three-stage transistor amplifier. The first two transistors in the amplifier served to buffer and amplify the current of the wavelet signal. These were NPN bipolar type biased for Class A operation. The third transistor was a MOSFET that controlled a 300 volt direct current power that was applied to a transmitting antenna.

As seen in FIG. 10, the inner ends of the antennas were grounded with 50 cm deep ground rods. The transmitter was connected to the right side of the right antenna and an oscilloscope was connected to the left side of the left antenna and to a ground rod there. Power supplies for the transmitter and an oscilloscope to record the transmission signals were powered by an AC inverter connected to a battery. The power supply for the receiving oscilloscope was powered by a separate AC inverter powered by a 12 volt battery. None of the power supplies were grounded.

Twelve volts direct current power were applied to the bipolar transistor circuit and a 150-270 volt direct current was applied to the MOSFET. An approximately 4.4 volt bias voltage obtained from a Zener diode regulated resistor divider was used to bias the MOSFET gate into its linear region. Total power consumption by the bipolar resistor portion of this circuit was about 2.5 watts and total power consumption by the MOSFET output stage (including loss in the series resistance and antenna resistance) was about 20 watts.

The receiver comprised a long antenna directly connected to an oscilloscope (Siglent Model SDS 1202X-E digital storage oscilloscope 200 MHz response and sampling 1 gigahertz/sec). The receiver absorbed photon energy created by accelerated electrons from the transmitting antenna and the connected oscilloscope displayed screen shots, which were recorded and shown as data for this study. The pulses shown in the figures represent data bits.

### Wavelet Generator

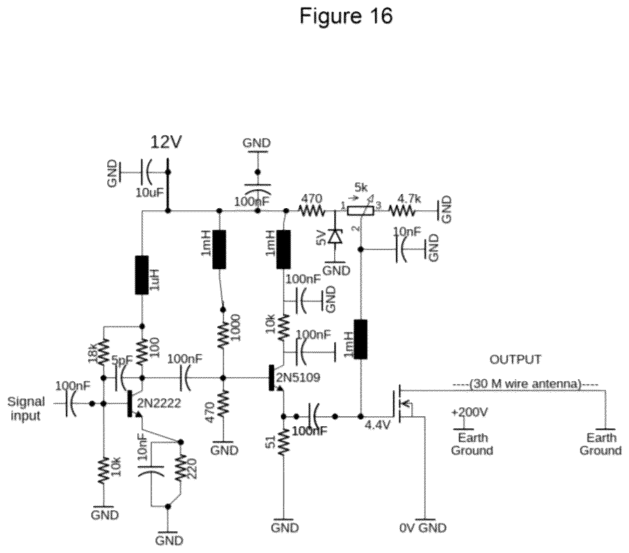

A frequency generator FeelTech FY3200S Dual Channel Signal Generator/Counter was adjusted to supply a sine wave input and a square wave input to the upper left connections shown in the schematic of FIG. 16 top. The data pin on the 74F74 D flip flop was set to ground. This data pin is driven by a data stream and switches between 180 degree reversed sines in an embodiment. The four JFET switches shown in the lower left of this schematic are in chip FST3125.

Wavelet Transmitter Combines Wavelet Generator with Amplifier

The circuit in FIG. 16 is an amplifier that accepts the combined sine/square wave signal prepared by FST3125 of the first circuit and inputs to the base of 2N2222, a bipolar transistor that is biased for class A voltage amplification. The output from the 2N2222 transistor is input to the 2N5109 transistor, which is biased for class A current amplification. The output from the 2N5109 transistor drives the gate of high voltage MOSFET IRF710. High voltage energy electrons enter the source pin of the MOSFET and exit the drain pin, which is connected directly to the antenna wire, allowing the transistor output to accelerate the metallic bond electrons in that metal wire. The other end of the antenna wire is connected via a 390 to 470 ohm resistor to earth ground, and the earth ground connects to the positive pole of the 300 volt power supply, allowing return of the electrons in the output circuit.

Electron accelerations were carried out in two directions. In a first direction, electron energy flowed from the transmitter into a transmitting antenna towards a receiver antenna. In the second direction, electron energy flowed from the transmitter into earth ground and then into the distal end of the transmitting antenna. The energy flowed back to the transmitter in a direction opposite from the receiver in this later case.

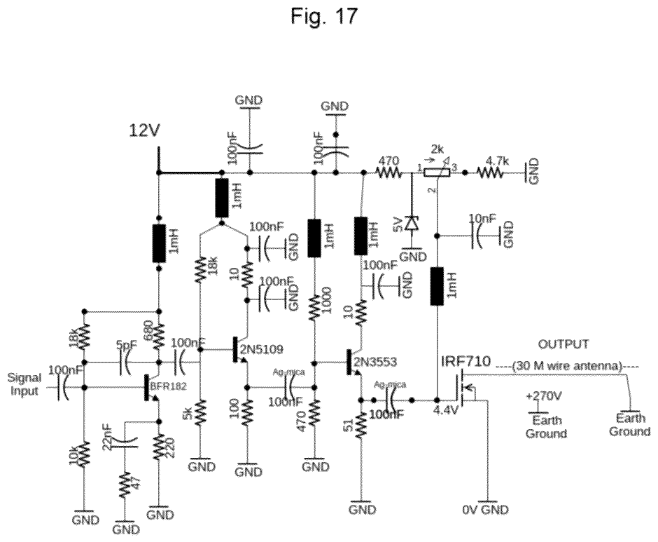

For the remaining examples, the 3 transistor amplifier described in FIG. 16 was replaced with the 4 transistor amplifier described in FIG. 17.

The latter 4 transistor amplifier allowed a stronger gate signal to the IRF710 MOSFET and use of a higher voltage to get a more linear output onto the antenna. The circuit shows an amplifier having a first voltage amplifier BFR182 followed by two current amplifiers 2N5109 and 2N3553. For some situations the additional current amplification, while surprising was a significant improvement. This extra amplification allowed a cleaner pulse to accelerate electrons in the transmitting antenna to create communication bits (0,1) as −1, +1 photon pulses. Using 360 degree (one wavelength duration) pulses in the transmitter, single sine wavelets of 360 degrees in opposite polarities were created in the receiver wire by changing the direction of electron flow into the transmitter antenna.

Use of fixed inter bit time. It was discovered that a crystal can absorb the energy of a 2-pi radian long photon pulse without resonating if allowed to relax for one 2-pi radian cycle. This relaxation pulse space in time between photon pulses can be fixed or varied, but was fixed for convenience in experiments. Another good reason to use fixed time spaces between pulses is to use the cadence to train a receiver to know when to look for pulses. By sending a series of identical pulses equally spaced apart in time, the receiver can learn the frequency of bit transmission and help remove noise via algorithms that reject signal energy that does not comport with the wave train cadence.

The claims and specific examples are not meant to limit the scope of the claimed invention and a skilled worker will readily apprehend broader implementations based on additional known art, which due to the need for brevity, could not be included here.

1. A photon pulse radio frequency transmitter that emits individual 2pi radian long cycle pulses of electromagnetic waves separated by non-energy blanking times;
comprising;
a reference signal that is used to time the 2pi radian long cycle pulses,
a non-resonant amplifier that directly connects to a non-resonant antenna by a connection circuit and outputs direct current of 2pi radian long cycle pulses of electromagnetic waves separated by non-energy blanking times into the non-resonant antenna without a resonant circuit.

2. The photon pulse radio frequency transmitter of claim 1, wherein each photon pulse cycle is separated by a single blank time period and data are sent as alternate phases of the photon pulse.

3. The photon pulse radio frequency transmitter of claim 1, wherein each photon pulse cycle comprises multiple 2pi radian long cycles and is separated by one or more blank times.

4. The photon pulse radio frequency transmitter of claim 1, further comprising a circuit that applies a low impedance to ground during blank periods between pulses to minimize harmonics in the signal.

5. The photon pulse radio frequency transmitter of claim 1, wherein the electromagnetic waves are radio short wave or radio long waves of frequency of between 100 khz and 50 MHz.

6. The photon pulse radio frequency transmitter of claim 1, wherein the transmitter emits a train of radio waves at multiple frequencies that vary according to a predetermined pattern.

7. The photon pulse radio frequency transmitter of claim 1, wherein the individual 2pi radian long cycle pulses of electromagnetic waves separated by non-energy blanking times comprise individual pulses of two types of reversed phase.

8. The photon pulse radio frequency transmitter of claim 7, wherein the connection circuit between the transmitter and antenna is configured to change the connection between the transmitter and the antenna at a rate corresponding to the frequency of a carrier signal to allow reversed direction emission for discrete waves at the carrier periodicity.

9. The photon pulse radio frequency transmitter of claim 1, wherein the connection circuit between the transmitter and antenna lacks capacitive coupling.

10. The photon pulse radio frequency transmitter of claim 1, comprising a non-resonant power output stage that comprises two power valves that switch power from the power output stage in opposite polarities between the power output stage and the antenna, and
a power valve drive circuit that accepts bit instructions directly or indirectly from a controller, and that switches the two or more power valves alternately in accordance with the bit instructions.

11. The photon pulse radio frequency transmitter of claim 8, further comprising at least one blanking circuit that asserts a low impedance to ground in between transmitted signal cycles.

12. A direct current radio frequency transmitter that emits selected individual 2pi radian long cycle pulses of electromagnetic waves, comprising:
a connection that accepts bit data from a controller;
a signal generator source for timing 2pi radian long cycle pulses; and
a non-resonant amplifier connected to a non-resonant antenna by direct current coupling;
wherein the bit data from the controller selects 2pi radian long cycle pulses for direct current transmission by the non-resonant antenna.

13. The direct current radio frequency transmitter of claim 12, comprising two valves that switch power from the power output stage in opposite polarities from the non-resonant amplifier to the antenna, and
a power valve drive circuit that accepts bit data from the controller, and that switches the two power valves oppositely in accordance with the bit data.

14. The direct current radio frequency transmitter of claim 12, wherein multiple individual 2 pi radian long cycle pulses of electromagnetic waves are separated by one or more blank times.

15. The direct current radio frequency transmitter of claim 13, that emits selected individual 2pi radian long cycle pulses of electromagnetic waves wherein the selected 2pi radian long cycle pulses comprise bipolar phase shift pulses and the connection circuit between the transmitter and antenna is reversed for each bipolar phase shift.

16. The direct current radio frequency transmitter of claim 12, further comprising at least one blanking circuit that asserts a low impedance to ground in between transmitted signal cycles.

17. A receiver for detecting a pulsed carrier transmission signal comprising:
a non-resonant antenna that generates an individual pulse in an electrical conductor in response to each received 2 pi radian radio wave pulse;
a non-resonant linear amplifier that accepts individual pulses of 2 pi radian duration each from the non-resonant antenna; and a zero crossing detector connected to the non-resonant amplifier without a resonant coupling; wherein the zero crossing detector outputs an electrical pulse in response to each zero crossing of the received pulsed carrier transmission signal.

18. The receiver of claim 17, wherein the zero crossing detector outputs negative pulses and positive pulses in response to negative zero crossing and positive zero crossing, respectively.

19. The receiver of claim 18, further comprising a circuit that determines time between zero crossings of the pulses to detect presence of a signal.

20. The receiver of claim 18, further comprising a missing pulse detector that determines if a missing pulse follows a positive zero crossing pulse or a negative zero crossing pulse.
